(19) United States
(12) Patent Application Publication
(10) Pub. No.: US 2023/0106649 A1
(43) Pub. Date: Apr. 6, 2023

(54) GRINDING APPARATUS

(71) Applicant: DISCO CORPORATION, Tokyo (JP)

(72) Inventors: Takenobu MORI, Tokyo (JP); Mai HANEDA, Tokyo (JP)

(21) Appl. No.: 17/936,532

(22) Filed: Sep. 29, 2022

(30) Foreign Application Priority Data
Oct. 1, 2021 (JP) 2021-162666

(51) Int. Cl. B24B 51/00; B24B 41/04

(52) U.S. Cl. CPC B24B 51/00; B24B 41/04

(57) ABSTRACT

A grinding apparatus acquires a ground-off quantity of a wafer that is being ground, by subtracting a vertical length |(H0−H1)| by which grindstones are worn that is acquired by an upper surface height measuring instrument that is selectively lifted and lowered in unison with a grinding mechanism from a distance |(Z0−Z1)| by which the grinding mechanism is lowered that is acquired by a Z-axis encoder coupled with the grinding mechanism. Since the ground-off quantity of the wafer is acquired using the upper surface height measuring instrument and the Z-axis encoder, it is not necessary to determine the ground-off quantity of the wafer with use of only an upper surface height measuring instrument disposed on a foundation, as has been customary heretofore.

### BACKGROUND OF THE INVENTION

### Field of the Invention

The present invention relates to a grinding apparatus.

### Description of the Related Art

As disclosed in Japanese Patent Laid-open Nos. 2008-073785 and 2019-130607, grinding apparatuses for grinding a workpiece held on a holding surface of a chuck table with use of grindstones measure a height of the holding surface and a height of an upper surface of the workpiece, calculate a difference between the height of the holding surface and the height of the upper surface of the workpiece, and grind the workpiece until the calculated difference reaches a predetermined value representing a desired thickness of the workpiece.

### SUMMARY OF THE INVENTION

According to the disclosed technology, in a case in which the thickness of a workpiece to be ground is large, it is necessary to use a measuring instrument having a wide measuring range for measuring a height of an upper surface of the workpiece. However, since the measuring instrument with the wide measuring range is expensive, it makes grinding apparatuses expensive if they incorporate the expensive measuring instrument.

As disclosed in Japanese Patent Laid-open No. 2021-020269, in a case in which an upper surface of an upstanding cylindrical ingot as a workpiece is ground, the grinding is carried out while reductions in the height of the upper surface of the workpiece are being measured. Inasmuch as the grindstones grind the workpiece as they press the workpiece, it is desirable to measure the height of the upper surface of the workpiece in the vicinity of a path traced by the grindstones.

It is an object of the present invention to provide a grinding apparatus for grinding a workpiece held on a chuck table while measuring a height of an upper surface of the workpiece with use of an upper surface height measuring instrument even if the thickness of the workpiece prior to being ground is in excess of a measuring range of the upper surface height measuring instrument.

In accordance with an aspect of the present invention, there is provided a grinding apparatus including a chuck table having a holding surface for holding a workpiece thereon, a grinding mechanism having grindstones for grinding an upper surface of the workpiece held on the holding surface, a grinding feed mechanism for selectively lifting and lowering the grinding mechanism in directions perpendicular to the holding surface, a height recognizing unit for recognizing a height of the grinding mechanism that is lifted or lowered by the grinding feed mechanism, an upper surface height measuring instrument for measuring a height of the upper surface of the workpiece held on the holding surface, and a control unit. The upper surface height measuring instrument is selectively lifted and lowered in unison with the grinding mechanism by the grinding feed mechanism in the directions perpendicular to the holding surface. The control unit includes a calculating section for calculating, while the grindstones are grinding the upper surface of the workpiece, a first calculation value according to the following equation:

|(Z0−Z1)|−|(H0−H1)|=the first calculation value,

where H0 represents a value measured by the upper surface height measuring instrument as representing a height of the same horizontal plane as lower surfaces of the grindstones, Z0 represents a value recognized by the height recognizing unit as representing the height of the grinding mechanism when the lower surfaces of the grindstones contact the workpiece, Z1 represents a value recognized by the height recognizing unit as representing the height of the grinding mechanism, the value varying in a downward direction, when the grinding mechanism is lowered to grind the workpiece, and H1 represents a measured value of the upper surface height measuring instrument that varies as the grindstones are worn while the grindstones are grinding the workpiece. The control unit controls the grinding feed mechanism to lower the grinding mechanism to grind the workpiece until the first calculation value calculated by the calculating section reaches a preset ground-off quantity.

Preferably, the control unit includes an upper surface height measuring instrument home position storage section for storing the value (H0) measured by the upper surface height measuring instrument as representing the height of the same horizontal plane as the lower surfaces of the grindstones, and the control unit determines that the lower surfaces of the grindstones contact the upper surface of the workpiece when a measured value of the upper surface height measuring instrument agrees with the value (H0) stored in the upper surface height measuring instrument home position storage section.

Preferably, the grinding apparatus further includes a foundation on which the chuck table and the grinding mechanism are disposed, and a holding surface height measuring instrument disposed on the foundation for measuring a height of the holding surface. In this case, the control unit includes a holding surface height measuring instrument home position storage section for storing a value (P0) measured by the holding surface height measuring instrument as representing the height of the holding surface when no vertical load is imposed on the holding surface. The calculating section calculates a second calculation value according to the following equation:

|(Z0−Z1)|−|(H0−H1)|−|(P1−P0)|=the second calculation value,

where P1 represents a value measured by the holding surface height measuring instrument as representing the height of the holding surface, the value varying in a downward direction as the chuck table sinks while the grindstones are grinding the workpiece. The control unit controls the grinding feed mechanism to lower the grinding mechanism to grind the workpiece until the second calculation value calculated by the calculating section reaches a preset ground-off quantity.

The grinding apparatus according to the aspect of the present invention acquires the ground-off quantity of the workpiece by subtracting the vertical length |(H0−H1)| by which grindstones are worn that is acquired by the upper surface height measuring instrument that is selectively lifted and lowered in unison with the grinding mechanism from the distance |(Z0−Z1)| by which the grinding mechanism is lowered that is acquired by the height recognizing unit while the grindstones are grinding the workpiece.

The grinding apparatus acquires the ground-off quantity of the workpiece with use of the height recognizing unit and the upper surface height measuring instrument that is selectively lifted and lowered in unison with the grinding mechanism. Consequently, it is not necessary to determine the ground-off quantity of the workpiece with use of only the upper surface height measuring instrument disposed on a foundation on which the chuck table and the like are disposed, for example, as has been customary heretofore. Accordingly, even if the thickness of the workpiece prior to being ground and the ground-off quantity of the workpiece are in excess of the measuring range of the upper surface height measuring instrument, the workpiece can be ground while the ground-off quantity of the workpiece held on the chuck table is being measured.

According to the aspect of the present invention, even if the measuring range of the upper surface height measuring instrument is not wide, it is possible to measure the ground-off quantity of a thick workpiece such as an ingot and also to measure the ground-off quantity of a thin workpiece. Therefore, the grinding apparatus does not need to have an expensive measuring instrument with a wide measuring range for grinding a thick workpiece, and hence remains less costly.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a side elevational view, partly in cross section, of a grinding apparatus according to an embodiment of the present invention;

FIG. 2 is a perspective view of an upper surface height measuring instrument incorporated in the grinding apparatus;

FIG. 3 is a cross-sectional view of the upper surface height measuring instrument illustrated in FIG. 2;

FIG. 4 is a side elevational view, partly in cross section, of the grinding apparatus, illustrating a ground-off quantity of a wafer being ground by the grinding apparatus;

FIG. 5 is a side elevational view, partly in cross section, of the grinding apparatus, illustrating a manner in which a setup block is used; and

FIG. 6 is a side elevational view, partly in cross section, of the grinding apparatus, illustrating a ground-off quantity of a wafer being ground by the grinding apparatus.

### DETAILED DESCRIPTION OF THE PREFERRED EMBODIMENT

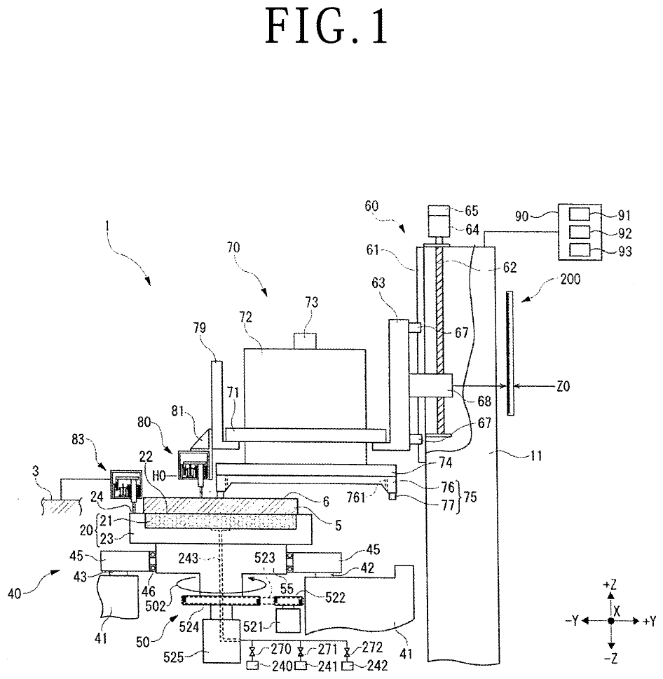

As illustrated in FIG. 1, a grinding apparatus 1 according to a preferred embodiment of the present invention is an apparatus for grinding a wafer 5 as a workpiece. The grinding apparatus 1 will be described in reference to a three-dimensional coordinate system having an X-axis, a Y-axis, and a Z-axis that are perpendicular to each other. Opposite directions along the X-axis will be referred to as a “+X direction” and a “−X direction” that extend horizontally, opposite directions along the Y-axis as a “+Y direction” and a “−Y direction” that extend horizontally, and opposite directions along the Z-axis as a “+Z direction” and a “−Z direction” that extend vertically.

The grinding apparatus 1 includes a chuck table 20 having a holding surface 22 for holding the wafer 5 under suction thereon. The chuck table 20 is rotatable about its vertical central axis. The chuck table 20 includes a porous member 21 and a frame 23 housing the porous member 21 that has an upper surface exposed upwardly. The upper surface of the porous member 21 functions as the holding surface 22. The holding surface 22 is fluidly connected to a suction source, to be described later, for generating suction forces that are applied to hold the wafer 5 under suction on the holding surface 22. The frame 23 has a radially outward upper surface as a frame surface 24 that lies flush with the holding surface 22.

The chuck table 20 is fixedly supported on a table base 55 disposed beneath the chuck table 20. The table base 55 is rotatably supported on a table rotating mechanism 50 disposed beneath the table base 55. The table rotating mechanism 50 rotates the table base 55 about its vertical central axis aligned with the vertical central axis of the chuck table 20.

The table rotating mechanism 50 includes an electric motor 521, a drive pulley 522 mounted on an output shaft of the electric motor 521, a driven pulley 524 operatively connected to the drive pulley 522 by an endless belt 523 trained around the drive and driven pulleys 522 and 524, and a rotary joint 525 disposed below the driven pulley 524. The table base 55 has a lower reduced-diameter portion that supports the driven pulley 524 fixedly thereon and that has a lower end rotatably connected to the rotary joint 525.

The table rotating mechanism 50 operates as follows. When the electric motor 521 is energized, it rotates the drive pulley 522, causing the endless belt 523 to rotate the driven pulley 524. As a result, the table base 55 and the chuck table 20 are rotated about their vertical central axes in a direction indicated by an arrow 502, for example.

A tilt adjusting mechanism 40 for adjusting a tilt of the chuck table 20 is disposed around the table base 55.

The tilt adjusting mechanism 40 includes an inner base 41 disposed below the chuck table 20, a tilt adjusting shaft 42, a fixed shaft 43 joined to the inner base 41, and an annular member 45.

The annular member 45 is disposed around the table base 55. The table base 55 is rotatably supported in the annular member 45 by a coupling mechanism 46 including bearings.

The fixed shaft 43 has an upper end joined to a lower surface of the annular member 45 and a lower end joined to an upper surface of the inner base 41.

The tilt adjusting shaft 42 is disposed between the inner base 41 and the annular member 45. The tilt adjusting shaft 42 can lift or lower a portion of the annular member 45 in the +Z direction or the −Z direction, thereby adjusting the tilt of the chuck table 20.

Although not illustrated, there is another fixed shaft joined to the inner base 41 and the annular member 45. Therefore, the annular member 45 is supported on the inner base 41 by the three shafts, one of which is the tilt adjusting shaft 42. According to the present invention, the fixed shafts may be dispensed with, and all of the three shafts may be tilt adjusting shafts.

A fluid channel 243 extends through the frame 23 of the chuck table 20, the table base 55, and the rotary joint 525. The fluid channel 243 has an upper end connected to the porous member 21 and a lower end connected to a suction source 240, an air source 241, and a water source 242 respectively through a suction valve 270, an air valve 271, and a water valve 272.

Consequently, the porous member 21 of the chuck table 20 can be supplied with air from the air source 241 and with water from the water source 242, and suction forces from the suction source 240 can be applied through the porous member 21 to the holding surface 22 thereof.

A vertical column 11 is erected at a position that is spaced from the chuck table 20 in the +Y direction. The column 11 supports thereon a grinding mechanism 70 for grinding the wafer 5 and a grinding feed mechanism 60 for moving the grinding mechanism 70 vertically.

The grinding feed mechanism 60 lifts and lowers the grinding mechanism 70 in the +Z direction and the −Z direction that are perpendicular to the holding surface 22 of the chuck table 20. The grinding feed mechanism 60 includes a Z-axis guide rail 61 extending parallel to the Z-axis, a Z-axis movable table 63 slidable on and along the Z-axis guide rail 61, a Z-axis ball screw 62 extending parallel to the Z-axis guide rail 61, a Z-axis electric motor 64, and a Z-axis encoder 65 for detecting a rotational angle of the Z-axis electric motor 64. The grinding mechanism 70 is mounted on the Z-axis movable table 63.

The Z-axis movable table 63 is slidably mounted on the Z-axis guide rail 61 by sliders 67. A nut 68 is fixed to the Z-axis movable table 63 and operatively threaded over the Z-axis ball screw 62. The Z-axis electric motor 64 is coupled to an upper end of the Z-axis ball screw 62.

The grinding feed mechanism 60 operates as follows. When the Z-axis electric motor 64 is energized, it rotates the Z-axis ball screw 62 about its central axis, causing the nut 68 to move the Z-axis movable table 63 along the Z-axis guide rail 61 in the +Z direction or the −Z direction. The grinding mechanism 70 mounted on the Z-axis movable table 63 is also moved in the +Z direction or the −Z direction.

The Z-axis encoder 65 functions as a height or vertical position recognizing unit. By detecting a rotational angle of the Z-axis electric motor 64, the Z-axis encoder 65 recognizes the height or vertical position of the grinding mechanism 70 that is lifted or lowered by the grinding feed mechanism 60. Specifically, the Z-axis encoder 65 determines, for example, a height of the nut 68 of the grinding feed mechanism 60 that moves in unison with the grinding mechanism 70 in the +Z direction or the −Z direction, as a height of the grinding mechanism 70.

The grinding mechanism 70 grinds an upper surface 6 of the wafer 5 held on the holding surface 22 of the chuck table 20 with use of grindstones 77. The grinding mechanism 70 includes a holder 79 fixed to the Z-axis movable table 63, a spindle housing 71 held on the holder 79, a spindle 72 rotatably held on the spindle housing 71, a spindle motor 73 for rotating the spindle 72 about its vertical central axis, a wheel mount 74 mounted on a lower end of the spindle 72, and a grinding wheel 75 supported on the wheel mount 74.

The spindle 72 extends along the Z-axis perpendicularly to the holding surface 22 of the chuck table 20. The spindle 72 is rotatably supported on the spindle housing 71 for rotation about its central axis along the Z-axis. The spindle motor 73 is coupled to an upper end of the spindle 72 for rotating the spindle 72.

The wheel mount 74 is shaped as a circular plate and fixed to a lower end, i.e., a distal end, of the spindle 72. The wheel mount 74 supports the grinding wheel 75 thereon.

The grinding wheel 75 is of a circular shape and has an outside diameter that is substantially the same as an outside diameter of the wheel mount 74. The grinding wheel 75 includes an annular wheel base 76 made of a metal material. The wheel base 76 has a processing water passage 761 defined therein for supplying processing water from a water source, not illustrated, to the grindstones 77.

The grindstones 77 are arranged in an annular array fully circumferentially on a lower surface of the wheel base 76 and fixed thereto. When the spindle 72 is rotated by the spindle motor 73, the grindstones 77 are also rotated in unison with the spindle 72, grinding the upper surface 6 of the wafer 5 held on the holding surface 22 of the chuck table 20.

The grinding apparatus 1 has an upper surface height measuring instrument 80 for measuring a height of the upper surface 6 of the wafer 5 held on the holding surface 22 of the chuck table 20. The upper surface height measuring instrument 80 is attached to the holder 79 of the grinding mechanism 70 by an attachment 81 and hence mounted on the grinding mechanism 70. Therefore, when the grinding mechanism 70 is lifted or lowered, the upper surface height measuring instrument 80 is also lifted or lowered in unison therewith in the +Z direction or the −Z direction perpendicular to the holding surface 22.

The upper surface height measuring instrument 80 should only be lifted or lowered in unison with the grinding mechanism 70 in the +Z direction or the −Z direction. Therefore, the upper surface height measuring instrument 80 may be mounted on a portion of the grinding feed mechanism 60 that is lifted or lowered in unison with the grinding mechanism 70.

The grinding apparatus 1 also has a holding surface height measuring instrument 83 for measuring a height of the holding surface 22 of the chuck table 20. The holding surface height measuring instrument 83 is disposed on a foundation 3 on which the chuck table 20 and the grinding mechanism 70 are disposed.

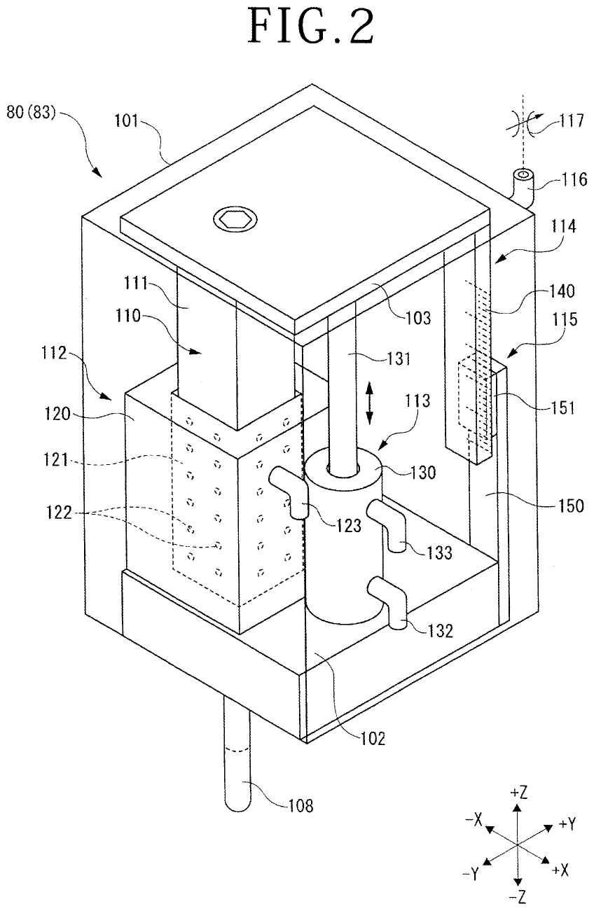

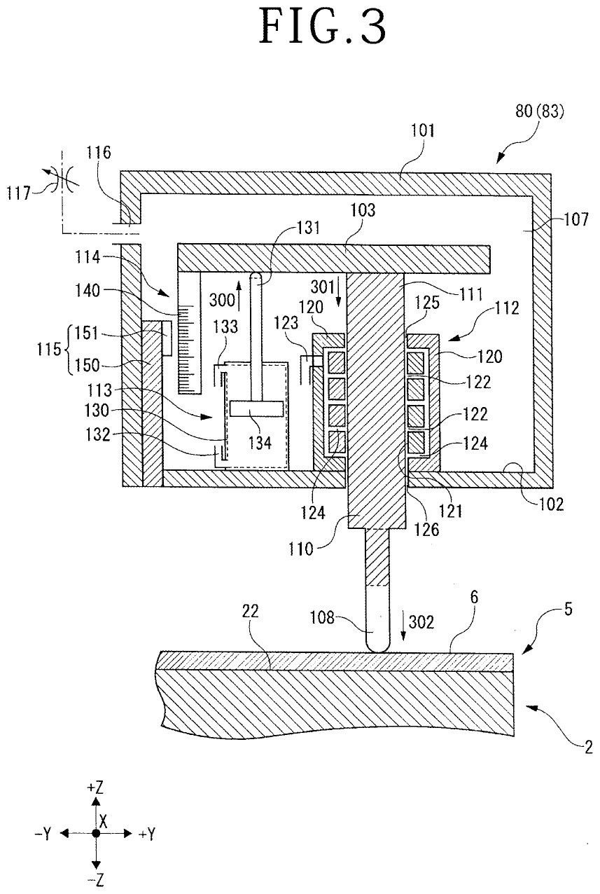

Structural details of the upper surface height measuring instrument 80 will be described below. The holding surface height measuring instrument 83 is structurally identical to the upper surface height measuring instrument 80, and hence its structural details will not be described below. As illustrated in FIGS. 2 and 3, the upper surface height measuring instrument 80 includes a probe 110 having a probe tip 108 for contacting the upper surface 6 of the wafer 5, a housing 112 by which the probe 110 is vertically movably supported in such a manner that the probe 110 can be lowered under its own weight, and a scale 114 for reading the height or vertical position of the probe 110.

According to the present embodiment, the upper surface height measuring instrument 80 also includes a moving mechanism 113 for moving the probe 110 along the Z-axis, a detecting mechanism 115 for reading graduations 140 of the scale 114, a discharge port 116 for discharging air, a variable restrictor valve 117 connected to the discharge port 116, and a case 101 as a casing that houses the probe 110, the housing 112, the moving mechanism 113, the scale 114, and the detecting mechanism 115.

The probe 110 has the probe tip 108 on its lower distal end and extends along the Z-axis perpendicularly to the holding surface 22. The probe 110 has an upper end coupled to a joint member 103.

The case 101 is supported on the holder 79 by the attachment 81 that is attached to an upper surface of the case 101, as illustrated in FIG. 1. As illustrated in FIGS. 2 and 3, the probe 110 is shaped as a quadrangular prism and extends vertically through the case 101 with the probe tip 108 protruding downwardly from a lower surface of the case 101.

The housing 112 surrounds side surfaces 111 of the probe 110 and supports the probe 110 out of contact therewith to allow the probe 110 to move along the Z-axis perpendicularly to the holding surface 22. Specifically, the housing 112 has a tube 120 accommodating the probe 110 and disposed on an inner support surface 102 of the case 101. The tube 120 has an upper hole having a square cross section defined in an upper wall thereof and a lower hole having a square cross section defined in a lower wall thereof. The upper and lower holes are complementary in cross-sectional shape to the probe 110. The probe 110 extends movably through the upper and lower holes out of contact with the housing 112.

The tube 120 also has inner vertical support surfaces 121 and a plurality of ejection openings 122 defined in the inner vertical support surfaces 121. The inner vertical support surfaces 121 face the side surfaces 111 of the probe 110 and are spaced therefrom by equal intervals.

As illustrated in FIG. 3, the tube 120 includes an inlet port 123 fluidly connected to an air source, not illustrated, and a passageway 124 joining the inlet port 123 and the ejection openings 122.

Air that is supplied from the air source to the inlet port 123 is ejected through the passageway 124 and the ejection openings 122 to the side surfaces 111 of the probe 110. Therefore, the housing 112 supports the probe 110 with a film of air interposed between the side surfaces 111 and the support surfaces 121.

The air introduced from the inlet port 123 into the tube 120 is discharged from the tube 120 through an upper discharge clearance 125 defined in the upper hole in the tube 120 between the probe 110 and the tube 120 and a lower discharge clearance 126 defined in the lower hole in the tube 120 between the probe 110 and the tube 120. The probe 110 is thus supported by the housing 112 out of contact therewith while being movable along the Z-axis.

The discharge port 116 discharges the air that has been discharged from the housing 112 into the case 101 out of the case 101. The variable restrictor valve 117 connected to the discharge port 116 adjusts a rate of air discharged from the discharge port 116 to regulate an air pressure in the case 101, adjusting a pressure by which the probe tip 108 is pressed against the upper surface 6 of the wafer 5.

The moving mechanism 113 is disposed on the inner support surface 102 of the case 101 near the probe 110. The moving mechanism 113 includes a cylinder 130 mounted on the inner support surface 102 and a piston 134 slidably fitted in the cylinder 130 for movement along the Z-axis parallel to the vertical axis of the probe 110. The piston 134 is connected to a piston rod 131 that extends upwardly out of the cylinder 130 and has an upper tip end for contact with the joint member 103.

The moving mechanism 113 also has a pair of inlet ports 132 and 133 connected to the cylinder 130 and an air source, not illustrated. The inlet port 132 opens into a rodless cavity of the cylinder 130, and the inlet port 133 opens into a rod cavity of the cylinder 130. When the moving mechanism 113 operates, the piston 134 is moved along the Z-axis, moving the probe 110 along the Z-axis.

Specifically, for lifting the probe 110 in the +Z direction, air from the air source is introduced through the inlet port 132 into the rodless cavity of the cylinder 130. The pressure buildup in the rodless cavity causes the piston 134 to move upwardly in the +Z direction in the cylinder 130, causing the piston rod 131 to contact and push the joint member 103 and hence the probe 110 upwardly in the +Z direction.

For lowering the probe 110 in the −Z direction, air from the air source is introduced through the inlet port 133 into the rod cavity of the cylinder 130. Due to the air pressure buildup in the rod cavity, the piston 134 is moved downwardly in the −Z direction in the cylinder 130, allowing the probe 110 and the joint member 103 to move downwardly in the −Z direction under their own weight.

The moving mechanism 113 can adjust a speed at which the piston 134 is lowered, thereby limiting a speed at which the probe 110 is lowered, by adjusting a rate of air introduced from the inlet port 133 into the rod cavity of the cylinder 130. The moving mechanism 113 can continuously lower the probe 110 until the probe tip 108 of the probe 110 contacts a surface below the probe 110, e.g., the upper surface 6 of the wafer 5 held on the holding surface 22 of the chuck table 20.

As illustrated in FIGS. 2 and 3, the scale 114 hangs from an end of the joint member 103 parallel to the Z-axis along which the probe 110 extends. The scale 114 is joined to the probe 110 by the joint member 103 and is movable along the Z-axis in unison with the probe 110.

The detecting mechanism 115 is disposed in the case 101 and attached to an end wall of the case 101. The detecting mechanism 115 includes a support plate 150 extending along the Z-axis and a detector 151 disposed on an upper end of the support plate 150. The detector 151 faces the graduations 140 of the scale 114 for reading the graduations 140. The detector 151 reads the graduations 140 of the scale 114 as the scale 114 moves along the Z-axis in unison with the probe 110, and thus, when the probe tip 108 contacts a surface below the probe 110, e.g., the upper surface 6 of the wafer 5, a height of the probe tip 108 can be detected.

As illustrated in FIG. 1, the grinding apparatus 1 further includes a control unit 90 having a central processing unit (CPU), a memory, and the like for controlling various components of the grinding apparatus 1 to grind the wafer 5 on the chuck table 20. The control unit 90 includes an upper surface height measuring instrument home position storage section 91, a calculating section 92, and a holding surface height measuring instrument home position storage section 93. The calculating section 92 is functionally realized by the CPU. A process of grinding the wafer 5 on the grinding apparatus 1 under the control of the control unit 90 will be described below. The process includes a sequence of steps.

### Holding Step:

An operator of the grinding apparatus 1 places the wafer 5 on the holding surface 22 of the chuck table 20 illustrated in FIG. 1, so that the wafer 5 is held on the holding surface 22 of the chuck table 20.

### Measuring Step:

Then, using a moving mechanism, not illustrated, the control unit 90 adjusts the position of the chuck table 20 to position a path traced by the grindstones 77 extends across the center of rotation of the wafer 5 on the holding surface 22 of the chuck table 20, i.e., the vertical central axis of the chuck table 20.

Thereafter, the control unit 90 controls the grinding feed mechanism 60 to lower the grinding mechanism 70 in order to bring lower surfaces of the grindstones 77 into contact with the upper surface 6 of the wafer 5. At this time, the control unit 90 keeps the probe 110 of the upper surface height measuring instrument 80 hanging from the case 101 under its own weight.

The probe tip 108 of the probe 110 contacts the upper surface 6 of the wafer 5 earlier than the lower surfaces of the grindstones 77. Until the lower surfaces of the grindstones 77 contact the upper surface 6 of the wafer 5, the probe 110 ascends relatively to the case 101 upon the continuing descent of the grinding mechanism 70, during which time the height of the probe tip 108 detected by the detector 151, i.e., the measured value of the upper surface height measuring instrument 80, varies.

When the control unit 90 recognizes that the measured value of the upper surface height measuring instrument 80 no longer varies, the control unit 90 determines that the lower surfaces of the grindstones 77 have contacted the upper surface 6 of the wafer 5. At this time, the control unit 90 acquires the value measured by the upper surface height measuring instrument 80 as representing the height of the upper surface 6 of the wafer 5, i.e., the value detected by the detector 151 as representing the height of the probe tip 108 contacting the upper surface 6 of the wafer 5, as H0. Thereafter, the control unit 90 controls the grinding feed mechanism 60 to lift the grinding mechanism 70.

The control unit 90 may alternatively acquire the value H0 immediately before the grindstones 77 start grinding the wafer 5 in a grinding step to be described below, i.e., when the lower surfaces of the grindstones 77 that are lowered contact the upper surface 6 of the wafer 5 in the grinding step.

### Grinding Step:

Then, the control unit 90 controls the spindle motor 73 of the grinding mechanism 70 to rotate the grindstones 77 with the spindle 72. The control unit 90 also controls the table rotating mechanism 50 to rotate the holding surface 22 of the chuck table 20 that is holding the wafer 5 thereon.

Then, the control unit 90 controls the grinding feed mechanism 60 to lower the grinding mechanism 70 toward the chuck table 20 until the rotating grindstones 77 contact the upper surface 6 of the wafer 5 that is being rotated.

When the lower surfaces of the grindstones 77 contact the upper surface 6 of the wafer 5, the control unit 90 acquires the value of the height of the grinding mechanism 70 that is recognized by the Z-axis encoder 65, as Z0. FIG. 1 illustrates a hypothetical scale 200 for indicating the height of the grinding mechanism 70 that is recognized by the Z-axis encoder 65. The control unit 90 may alternatively acquire the value Z0 at the time the upper surface height measuring instrument 80 acquires the value H0 in the measuring step.

Thereafter, the control unit 90 controls the grinding feed mechanism 60 to further lower the grinding mechanism 70 to cause the grindstones 77 to grind the upper surface 6 of the wafer 5. While the grindstones 77 are grinding the upper surface 6 of the wafer 5, the control unit 90 keeps the probe 110 of the upper surface height measuring instrument 80 hanging from the case 101 under its own weight, thereby holding the probe tip 108 in contact with the upper surface 6 of the wafer 5 that is in the same horizontal plane as the lower surfaces of the grindstones 77.

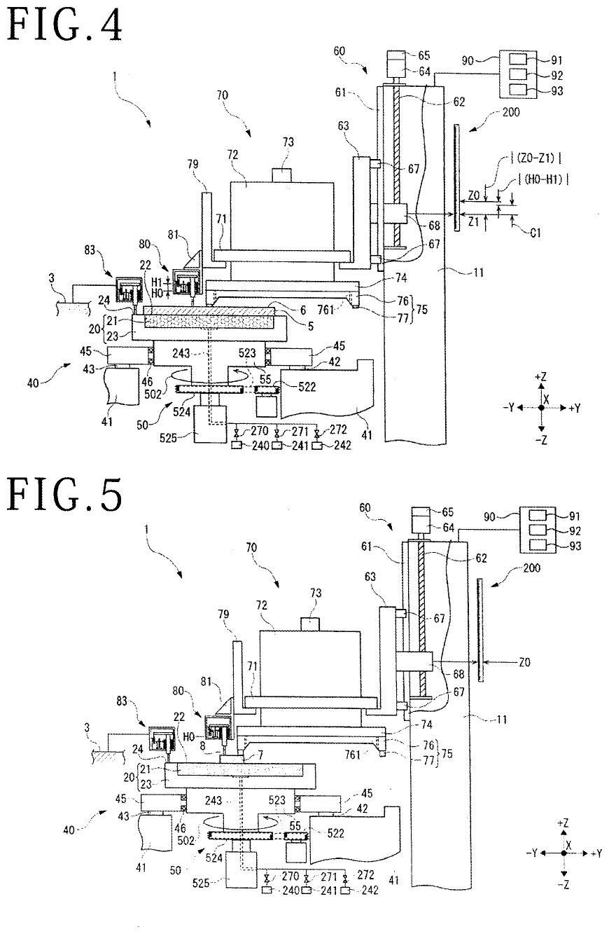

Then, as illustrated in FIG. 4, the control unit 90 acquires the value of the height of the grinding mechanism 70 that is recognized by the Z-axis encoder 65, which value varies in a downward direction or the −Z direction in which the grinding mechanism 70 is lowered, i.e., becomes smaller, when the grinding mechanism 70 is lowered to grind the wafer 5, as Z1.

As the grindstones 77 grind the wafer 5, the grindstones 77 are worn, having their vertical length shortened. Consequently, the probe tip 108 of the upper surface height measuring instrument 80 that is held in contact with the upper surface 6 of the wafer 5 that is being ground becomes closer along the Z-axis to the detector 151 of the upper surface height measuring instrument 80 by a distance commensurate with the vertical length by which the grindstones 77 are worn. As a result, the measured value of the upper surface height measuring instrument 80, i.e., the value of the height of the probe tip 108 detected by the detector 151, varies in an upward direction, i.e., becomes larger, by a value commensurate with the vertical length by which the grindstones 77 are worn.

Then, the control unit 90 acquires the measured value of the upper surface height measuring instrument 80 that varies in the upward direction due to the wear of the grindstones 77 while they are grinding the wafer 5, as H1 as illustrated in FIG. 4.

While the grindstones 77 are grinding the wafer 5, the calculating section 92 of the control unit 90 calculates a first calculation value C1 according to the following equation:

|(Z0−Z1)|−|(H0−H1)|=C1

The first calculation value C1 represents a value obtained by subtracting the vertical length |(H0−H1)| by which the grindstones 77 are worn in the grinding step from the distance |(Z0−Z1)| by which the grinding mechanism 70 is lowered, and corresponds to a ground-off quantity, i.e., a ground-off thickness, of the wafer 5. A relation between |(Z0−Z1)|, |(H0−H1)|, and C1 is illustrated in the vicinity of the scale 200 in FIG. 4.

The control unit 90 controls the grinding mechanism 70 to cause the grindstones 77 to grind the wafer 5 until the first calculation value C1 calculated by the calculating section 92 reaches a preset ground-off quantity. When the first calculation value C1 has reached the preset ground-off quantity, the control unit 90 determines that the wafer 5 has reached a predetermined thickness, and controls the grinding feed mechanism 60 to lift the grinding mechanism 70, thereby finishing the grinding step.

According to the present embodiment, as described above, the ground-off quantity of the wafer 5 is acquired by subtracting the vertical length |(H0−H1)| by which the grindstones 77 are worn that is acquired by the upper surface height measuring instrument 80 that is lifted and lowered in unison with the grinding mechanism 70 from the distance |(Z0−Z1)| by which the grinding mechanism 70 is lowered that is acquired by the Z-axis encoder 65 while the wafer 5 is being ground.

According to the present embodiment, the ground-off quantity of the wafer 5 is measured using the Z-axis encoder 65 and the upper surface height measuring instrument 80 that is lifted and lowered in unison with the grinding mechanism 70. Consequently, it is not necessary to determine the ground-off quantity of the wafer 5 with use of only an upper surface height measuring instrument on the foundation 3 of the grinding apparatus 1. Even if the thickness of the wafer 5 prior to being ground and the ground-off quantity of the wafer 5 are in excess of a measuring range of the upper surface height measuring instrument 80, the wafer 5 can be ground while the ground-off quantity of the wafer 5 held on the chuck table 20 is being measured.

According to the present embodiment, even if the measuring range of the upper surface height measuring instrument 80 is not wide, it is possible to measure the ground-off quantity of a thick workpiece such as an ingot and also to measure the ground-off quantity of a thin workpiece. Therefore, the grinding apparatus 1 does not need to have an expensive measuring instrument with a wide measuring range for grinding a thick workpiece, and hence remains less costly.

According to the present embodiment, furthermore, the upper surface height measuring instrument 80 is attached to the grinding mechanism 70 by the attachment 81. Therefore, the upper surface height measuring instrument 80 can measure the height of the upper surface 6 of the wafer 5 near the path traced by the grindstones 77.

According to the present embodiment, the lower surfaces of the grindstones 77 are held in contact with the upper surface 6 of the wafer 5 at the time the value H0 measured by the upper surface height measuring instrument 80 is acquired as representing a height of the same horizontal plane as the lower surfaces of the grindstones 77. Alternatively, as illustrated in FIG. 5, a setup block 7 having a predetermined thickness may be held on the upper surface 6 of the wafer 5 for acquiring the value H0. Specifically, when the setup block 7 is used, the control unit 90 acquires the value measured by the upper surface height measuring instrument 80 as representing a height of an upper surface 8 of the setup block 7 in the same horizontal plane as the lower surfaces of the grindstones 77, as H0. The value H0 thus acquired is commensurate with the vertical length of the grindstones 77 prior to being worn due to the grinding process, as is the case with the value H0 of the height of the probe tip 108 measured while the lower surfaces of the grindstones 77 are held in contact with the upper surface 6 of the wafer 5. Therefore, as with the above embodiment, the vertical length |(H0−H1)| by which the grindstones 77 are worn can well be measured.

The setup block 7 may be placed on the holding surface 22.

The thickness of the setup block 7 is accurately recognized by the control unit 90. Consequently, the control unit 90 can recognize a distance that the grinding mechanism 70 is to be lowered, i.e., a grinding feed distance, for grinding the wafer 5 to a predetermined thickness, on the basis of the height of the grinding mechanism 70 at the time the lower surfaces of the grindstones 77 have contacted the upper surface 8 of the setup block 7 and the thickness of the setup block 7.

After having acquired the value H0 measured by the upper surface height measuring instrument 80 as representing the height of the same horizontal plane as the lower surfaces of the grindstones 77, e.g., the upper surface 6 of the wafer 5 or the upper surface 8 of the setup block 7, the control unit 90 may store the acquired value H0 in the upper surface height measuring instrument home position storage section 91. The control unit 90 can thus repeatedly use the value H0 as representing data related to the vertical length of the grindstones 77 before they are worn.

Moreover, when the grinding mechanism 70 is to grind the wafer 5 held on the holding surface 22 of the chuck table 20, the control unit 90 controls the grinding feed mechanism 60 to lower the grinding mechanism 70 downwardly toward the wafer 5. When the measured value of the upper surface height measuring instrument 80 agrees with the value H0 stored in the upper surface height measuring instrument home position storage section 91, the control unit 90 can determine that the lower surfaces of the grindstones 77 have contacted the upper surface 6 of the wafer 5.

Specifically, as described above, when the grinding mechanism 70 is lowered for grinding the wafer 5, the probe tip 108 of the probe 110 hanging from the case 101 under its own weight contacts the upper surface 6 of the wafer 5 earlier than the lower surfaces of the grindstones 77. Until the lower surfaces of the grindstones 77 contact the upper surface 6 of the wafer 5, the probe 110 ascends relatively to the case 101 upon the continuing descent of the grinding mechanism 70, during which time the height of the probe tip 108 detected by the detector 151, i.e., the measured value of the upper surface height measuring instrument 80, becomes closer to the value H0. Therefore, the control unit 90 can determine that the lower surfaces of the grindstones 77 have contacted the upper surface 6 of the wafer 5 by recognizing that the measured value of the upper surface height measuring instrument 80 has reached H0.

With this arrangement, the control unit 90 can easily acquire the timing of the lower surfaces of the grindstones 77 contacting the upper surface 6 of the wafer 5. Consequently, for example, the control unit 90 is able to acquire with ease the value Z0 recognized by the Z-axis encoder 65 as representing the height of the grindstones 77 at the time the lower surfaces of the grindstones 77 contact the upper surface 6 of the wafer 5.

According to the present embodiment, the ground-off quantity of the wafer 5 may be acquired using a distance that the chuck table 20 sinks in addition to the distance that the grinding mechanism 70 is lowered and the vertical length by which the grindstones 77 are worn. The distance that the chuck table 20 sinks is measured by the holding surface height measuring instrument 83. The holding surface height measuring instrument 83 measures a height of the frame surface 24 of the frame 23 of the chuck table 20, thereby measuring the height of the holding surface 22 that lies flush with the frame surface 24.

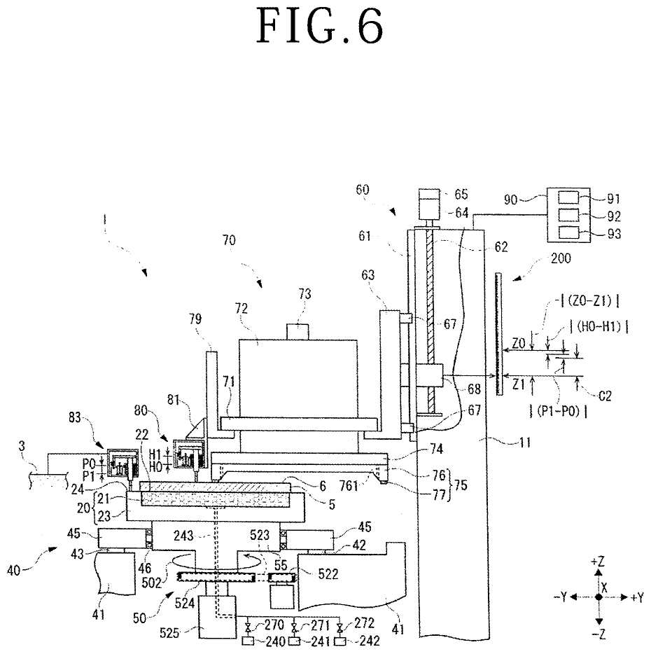

As illustrated in FIG. 6, when there is no vertical load imposed on the holding surface 22 of the chuck table 20, the control unit 90 controls the holding surface height measuring instrument 83 to measure the height of the holding surface 22, acquires the measured value as P0, and stores the measured value P0 in the holding surface height measuring instrument home position storage section 93, for example, after the holding step of holding the wafer 5 on the holding surface 22 of the chuck table 20 and before the grindstones 77 contact the wafer 5 in the grinding step.

Thereafter, when the control unit 90 controls the grinding feed mechanism 60 to lower the grinding mechanism 70 to cause the grindstones 77 to grind the upper surface 6 of the wafer 5, the control unit 90 also controls the holding surface height measuring instrument 83 to keep the probe tip 108 of the probe 110 thereof in contact with the frame surface 24.

When the grindstones 77 grinds the wafer 5, the chuck table 20 sinks because the grindstones 77 press the holding surface 22 downwardly. Therefore, the height of the holding surface 22 that is measured by the holding surface height measuring instrument 83 is reduced. When the grindstones 77 grinds the wafer 5, the control unit 90 acquires the values H1 and Z1 described above and also acquires the measured value of the holding surface height measuring instrument 83 that varies in a downward direction, i.e., becomes smaller, due to the sinking of the chuck table 20, as P1.

The calculating section 92 of the control unit 90 calculates a second calculation value C2 according to the following equation:

|(Z0−Z1)|−|(H0−H1)|−|(P1−P0)|=C2

The second calculation value C2 represents a value obtained by subtracting the vertical length |(H0−H1)| by which the grindstones 77 are worn in the grinding step and the distance |(P1−P0)| by which the chuck table 20 sinks from the distance |(Z0−Z1)| by which the grinding mechanism 70 is lowered, and corresponds to a ground-off quantity, i.e., a ground-off thickness, of the wafer 5. A relation between |(Z0−Z1)|, |(H0−H1)|, |(P1−P0)|, and C2 is illustrated in the vicinity of the scale 200 in FIG. 6.

The control unit 90 controls the grinding mechanism 70 to cause the grindstones 77 to grind the wafer 5 until the second calculation value C2 calculated by the calculating section 92 reaches a preset ground-off quantity. When the second calculation value C2 has reached the preset ground-off quantity, the control unit 90 determines that the wafer 5 has reached a predetermined thickness, and controls the grinding feed mechanism 60 to lift the grinding mechanism 70, thereby finishing the grinding step.

With the arrangement illustrated in FIG. 6, the ground-off quantity of the wafer 5 is measured using the distance that the chuck table 20 sinks in addition to the distance that the grinding mechanism 70 is lowered and the vertical length by which the grindstones 77 are worn. Therefore, it is possible to measure the ground-off quantity of the wafer 5 more accurately.

According to the present embodiment, the upper surface height measuring instrument 80 is mounted on the grinding mechanism 70 and measures the height of the same horizontal plane as the grindstones 77 with use of the probe 110. However, as long as the upper surface height measuring instrument 80 can be lifted and lowered in unison with the grinding mechanism 70 and can measure the height of the same horizontal plane as the grindstones 77 with the measured value being variable as the grindstones 77 are worn, the upper surface height measuring instrument may be of a structure free of the probe 110. For example, the upper surface height measuring instrument 80 may be a laser beam or sound wave distance measuring instrument combined with the grinding mechanism 70 for measuring the height of the same horizontal plane as the grindstones 77 out of contact with a workpiece. The laser beam or sound wave distance measuring instrument applies a laser beam or a sound wave to a workpiece surface on same the horizontal plane as the grindstones 77 and measures a height of the surface on the basis of the laser beam or the sound wave reflected from the workpiece surface.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding apparatus comprising:
a chuck table having a holding surface for holding a workpiece thereon;
a grinding mechanism having grindstones for grinding an upper surface of the workpiece held on the holding surface;
a grinding feed mechanism for selectively lifting and lowering the grinding mechanism in directions perpendicular to the holding surface;
a height recognizing unit for recognizing a height of the grinding mechanism that is lifted or lowered by the grinding feed mechanism;
an upper surface height measuring instrument for measuring a height of the upper surface of the workpiece held on the holding surface; and
a control unit,
wherein the upper surface height measuring instrument is selectively lifted and lowered in unison with the grinding mechanism by the grinding feed mechanism in the directions perpendicular to the holding surface,
wherein the control unit includes a calculating section for calculating, while the grindstones are grinding the upper surface of the workpiece, a first calculation value according to the following equation:

|(Z0−Z1)|−|(H0−H1)|=the first calculation value,
where H0 represents a value measured by the upper surface height measuring instrument as representing a height of a same horizontal plane as lower surfaces of the grindstones,
Z0 represents a value recognized by the height recognizing unit as representing the height of the grinding mechanism when the lower surfaces of the grindstones contact the workpiece,
Z1 represents a value recognized by the height recognizing unit as representing the height of the grinding mechanism, the value varying in a downward direction, when the grinding mechanism is lowered to grind the workpiece, and
H1 represents a measured value of the upper surface height measuring instrument that varies as the grindstones are worn while the grindstones are grinding the workpiece, and
wherein the control unit controls the grinding feed mechanism to lower the grinding mechanism to grind the workpiece until the first calculation value calculated by the calculating section reaches a preset ground-off quantity.

2. The grinding apparatus according to claim 1,
wherein the control unit includes an upper surface height measuring instrument home position storage section for storing the value (H0) measured by the upper surface height measuring instrument as representing the height of the same horizontal plane as the lower surfaces of the grindstones, and
wherein the control unit determines that the lower surfaces of the grindstones contact the upper surface of the workpiece when a measured value of the upper surface height measuring instrument agrees with the value (H0) stored in the upper surface height measuring instrument home position storage section.

3. The grinding apparatus according to claim 1, further comprising:
a foundation on which the chuck table and the grinding mechanism are disposed; and
a holding surface height measuring instrument disposed on the foundation for measuring a height of the holding surface,
wherein the control unit includes a holding surface height measuring instrument home position storage section for storing a value (P0) measured by the holding surface height measuring instrument as representing the height of the holding surface when no vertical load is imposed on the holding surface,
wherein the calculating section calculates a second calculation value according to the following equation:

|(Z0−Z1)|−|(H0−H1)|−|(P1−P0)|=the second calculation value,
where P1 represents a value measured by the holding surface height measuring instrument as representing the height of the holding surface, the value varying in a downward direction as the chuck table sinks while the grindstones are grinding the workpiece, and
wherein the control unit controls the grinding feed mechanism to lower the grinding mechanism to grind the workpiece until the second calculation value calculated by the calculating section reaches a preset ground-off quantity.
